(19) United States
(12) Patent Application Publication
(10) Pub. No.: US 2010/0261311 A1
(43) Pub. Date: Oct. 14, 2010

(54) METHOD OF MANUFACTURING A SEMICONDUCTOR DEVICE

(75) Inventor: Daisuke TSUJI, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/755,915

(22) Filed: Apr. 7, 2010

(30) Foreign Application Priority Data
Apr. 10, 2009 (JP) 2009-095798

(51) Int. Cl. H01L 21/77; H01L 21/56

(52) U.S. Cl. 438/109; 438/124; 257/E21.503; 257/E21.598

(57) ABSTRACT

A chip stack is created by stacking a plurality of semiconductor chips while connecting respective through electrodes of the semiconductor chips to each other, and forming a first sealing resin layer for covering the periphery of the plurality of stacked semiconductor chips, and filling gaps between the semiconductor chips. Subsequently, the chip stack is fixed on a supporting board or a wiring board which is formed with predetermined wiring.

### BACKGROUND OF THE INVENTION

1. Field of the Invention

The present invention relates to a method of manufacturing a CoC (Chip on Chip) type semiconductor device.

2. Description of the Related Art

In recent years, with the increasing reduction in size and higher performance of electronic devices, investigations have been under progress for a CoC type semiconductor device which comprises a plurality of stacked semiconductor chips, each having through electrodes.

A known method of manufacturing a CoC type semiconductor device involves sequentially stacking a plurality of semiconductor chips, each having through electrodes, on a wiring board or a supporting board, filling gaps between the respective semiconductor chips with an underfill material, and then entirely sealing the plurality of semiconductor chips, including the underfill material, with a resin.

Such background art methods of manufacturing a CoC type semiconductor device are described for example, in Japanese Patent Laid-Open No. 2006-319243 and Japanese Patent Laid-Open No. 2007-36184A.

However, in the foregoing background art method of manufacturing a semiconductor device, since a plurality of semiconductor chips are sequentially stacked on a wiring board or a supporting board, the resulting semiconductor device is susceptible to rupture of connections between semiconductor chips, and cracks occurring in semiconductor chips, due to thermal stresses caused by a variety of heat treatments performed during the manufacturing, which are attributable to the difference in the thermal expansion coefficient and rigidity between the semiconductor chips and the wiring board, the difference in thermal expansion coefficient and rigidity between the semiconductor chips and the supporting board, or to variations in thermal distribution over the semiconductor device, and the like.

Also, since the shape of the fillets formed around the underfill material is not stable while the underfill material is supplied, the underfill material can spread over to increase the width of the fillets, resulting in a larger package size.

### SUMMARY OF THE INVENTION

In one embodiment, there is provided a method of manufacturing a semiconductor device according to the present invention that comprises:

stacking a plurality of semiconductor chips while connecting respective through electrodes of the semiconductor chips to each other;

forming a first sealing resin layer for covering the periphery of the plurality of stacked semiconductor chips, and filling gaps between the semiconductor chips;

securely connecting a chip stack including the plurality of stacked semiconductor chips and the first sealing resin layer to a wiring board which is formed with predetermined wiring; and

forming a second sealing resin layer for covering the entire chip stack on the wiring board.

Another method of manufacturing a semiconductor device according to the present invention comprises:

stacking a plurality of semiconductor chips while connecting respective through electrodes of the semiconductor chips to each other;

forming a first sealing resin layer for covering the periphery of the plurality of stacked semiconductor chips, and filling gaps between the semiconductor chips;

fixing a chip stack including the plurality of stacked semiconductor chips and the first sealing resin layer onto a supporting board;

forming a second sealing resin layer for covering the entire chip stack on the supporting board except for a surface of the chip stack opposing a fixing surface of the supporting board; and

securely connecting a wiring board formed with a predetermined wiring pattern to the surface of the chip stack opposing the fixing surface of the supporting board.

In the methods of manufacturing a semiconductor device as described above, the chip stack is previously created to include a plurality of stacked semiconductor chips, and then, the chip stack is securely connected to the wiring board or supporting board, so that thermal stresses applied to connections between the semiconductor chips and to the semiconductor chips can be reduced in heat treatments performed during the manufacturing, the stress being attributable to the difference in thermal expansion coefficient and rigidity between the semiconductor chips and the wiring board, the difference in thermal expansion coefficient and rigidity between the semiconductor chips and the supporting board, variations in thermal distribution of the entire semiconductor device, and the like. Consequently, the rupture of connections between the semiconductor chips and the occurrence of cracks in the semiconductor chips can be prevented.

The above and other objects, features, and advantages of the present invention will become apparent from the following description with reference to the accompanying drawings, which illustrate examples of the present invention.

### BRIEF DESCRIPTION OF THE DRAWINGS

FIG. 1 is a cross-sectional view showing an exemplary configuration of a semiconductor device according to a first embodiment;

FIG. 2A is a perspective view showing an exemplary configuration of an adsorption stage for use in the manufacturing of the chip stack shown in

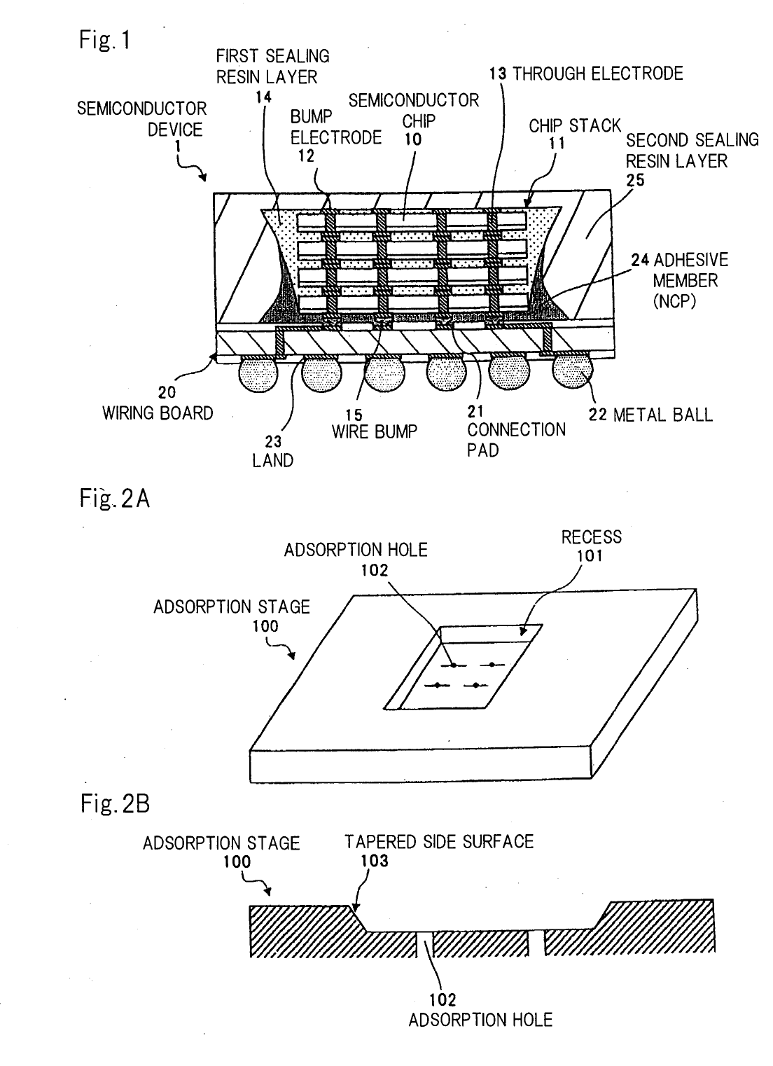

FIG. 1;

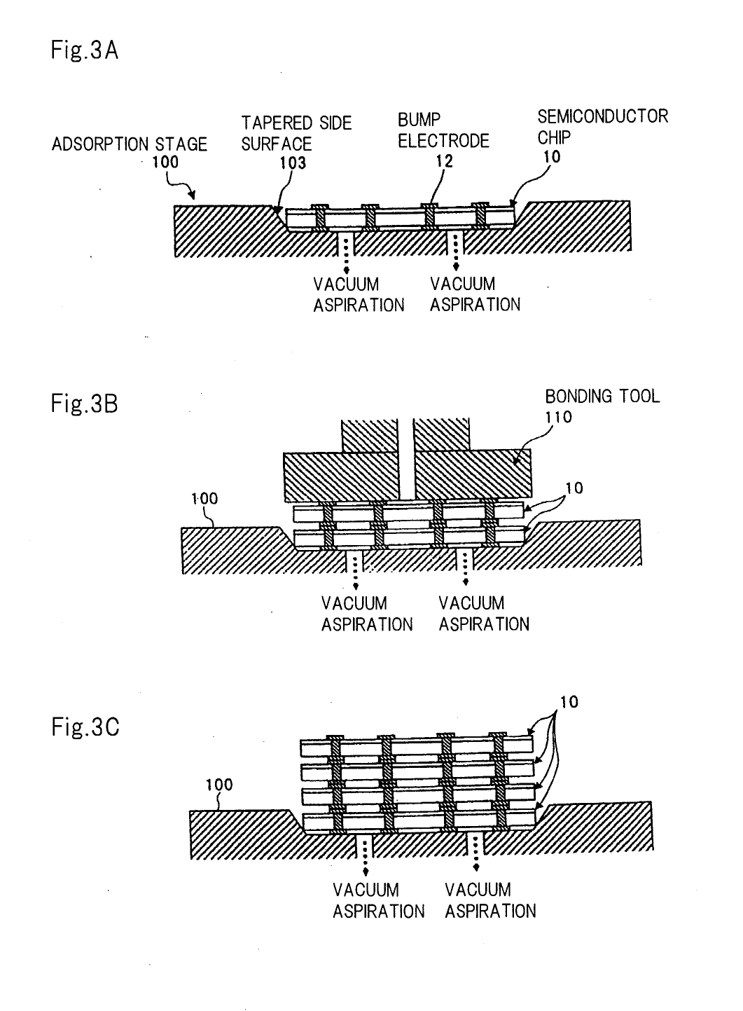

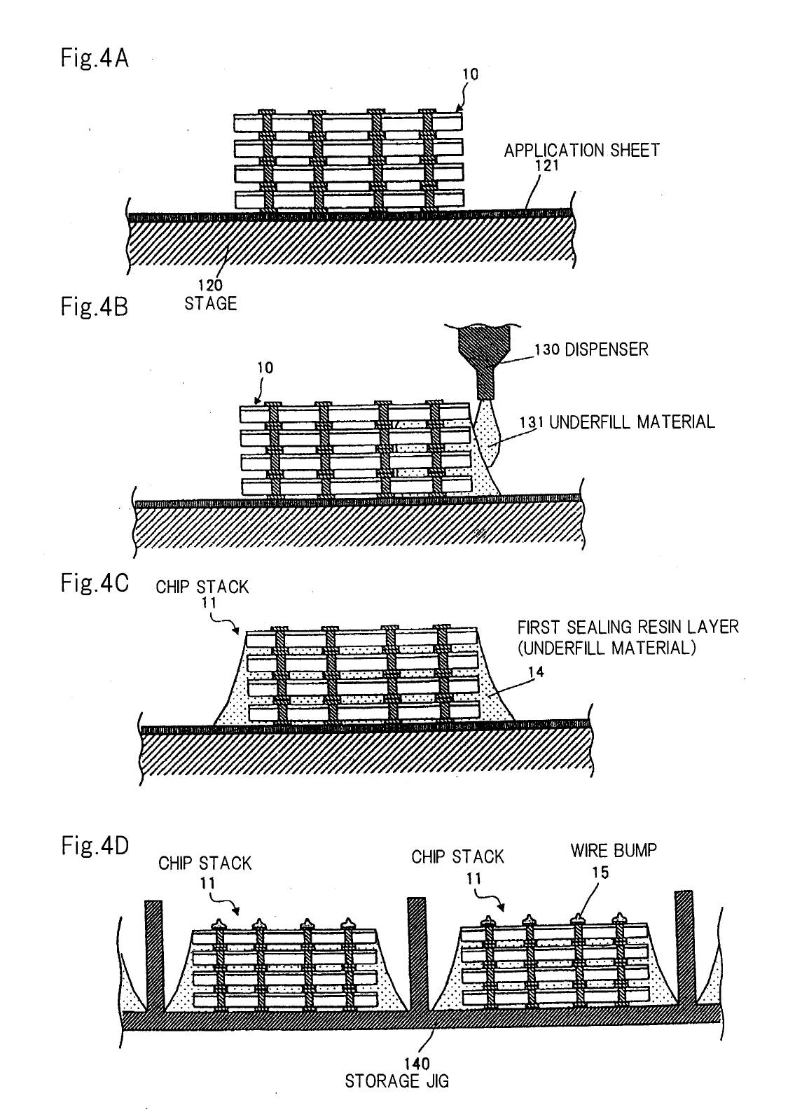

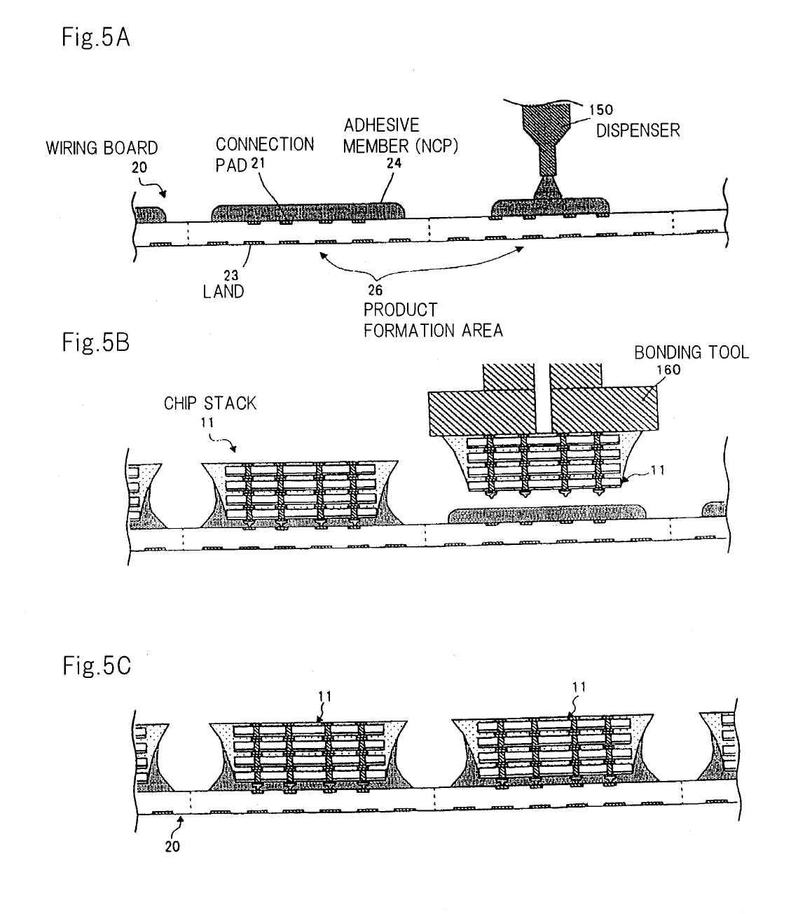

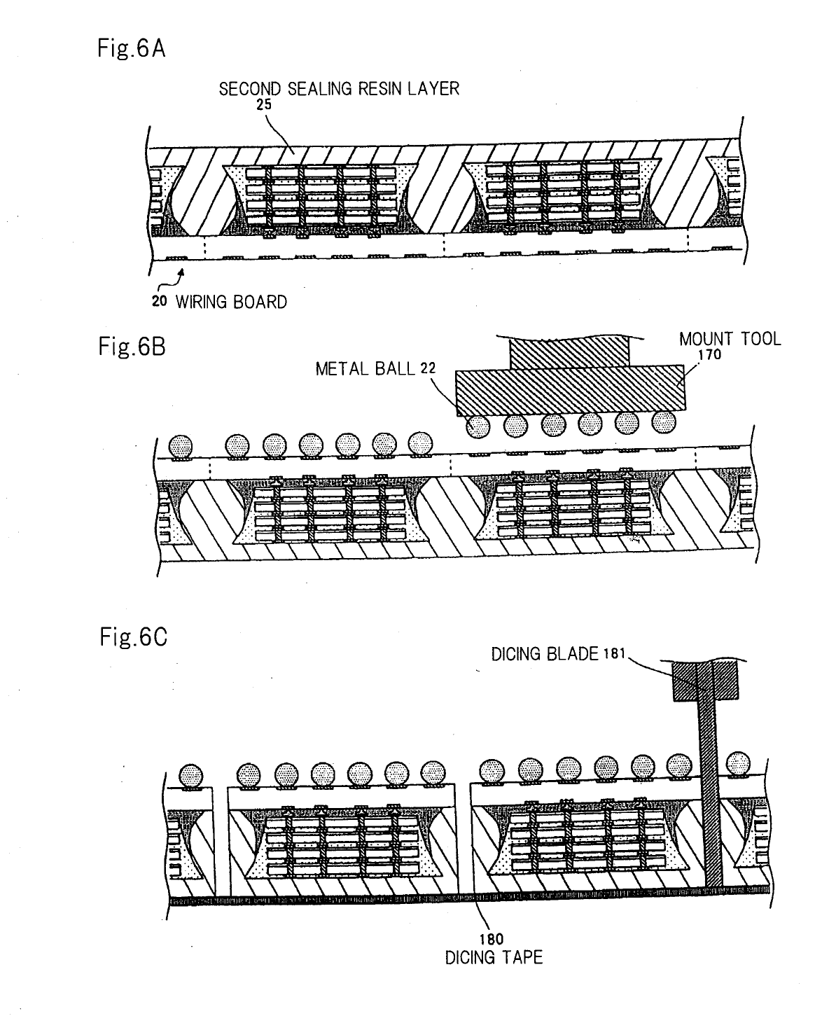

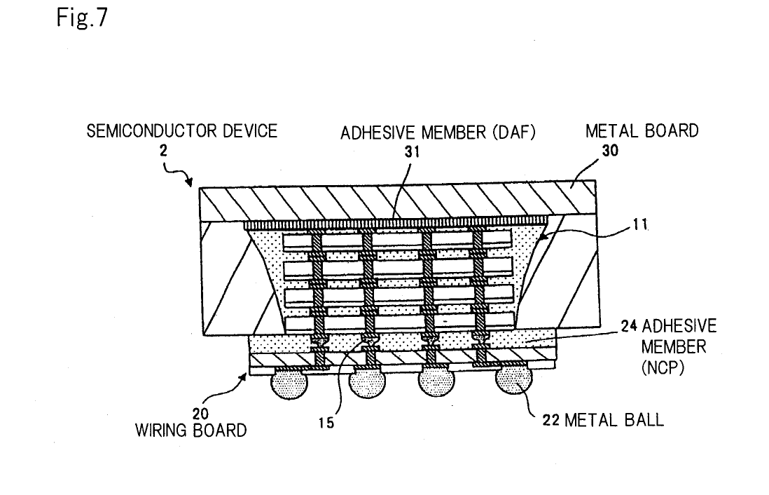

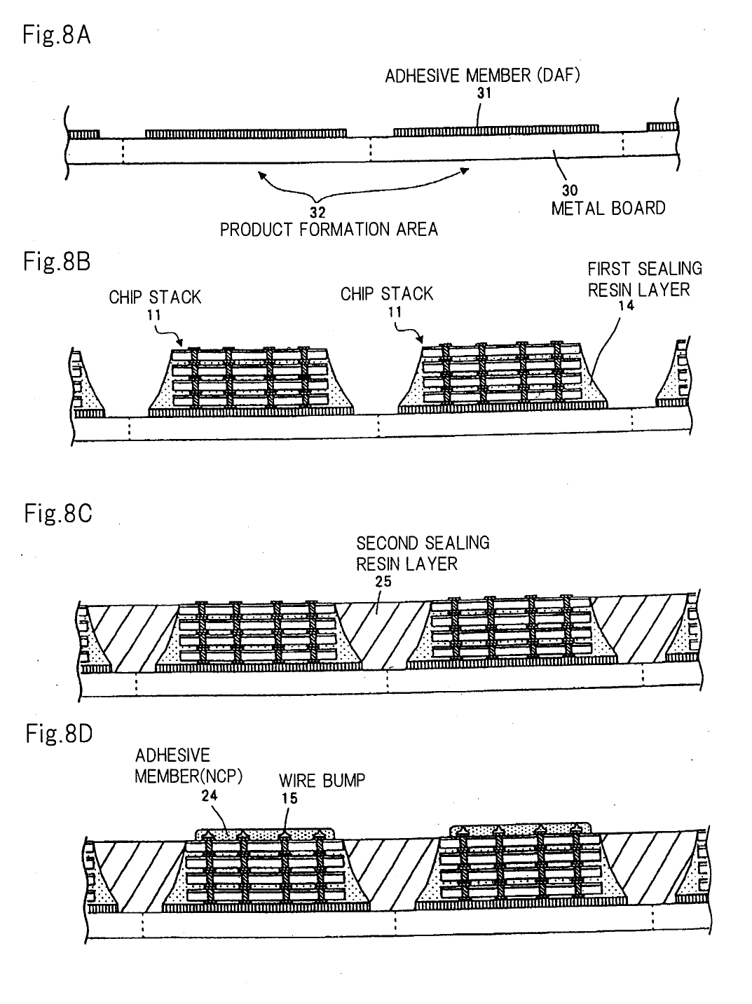

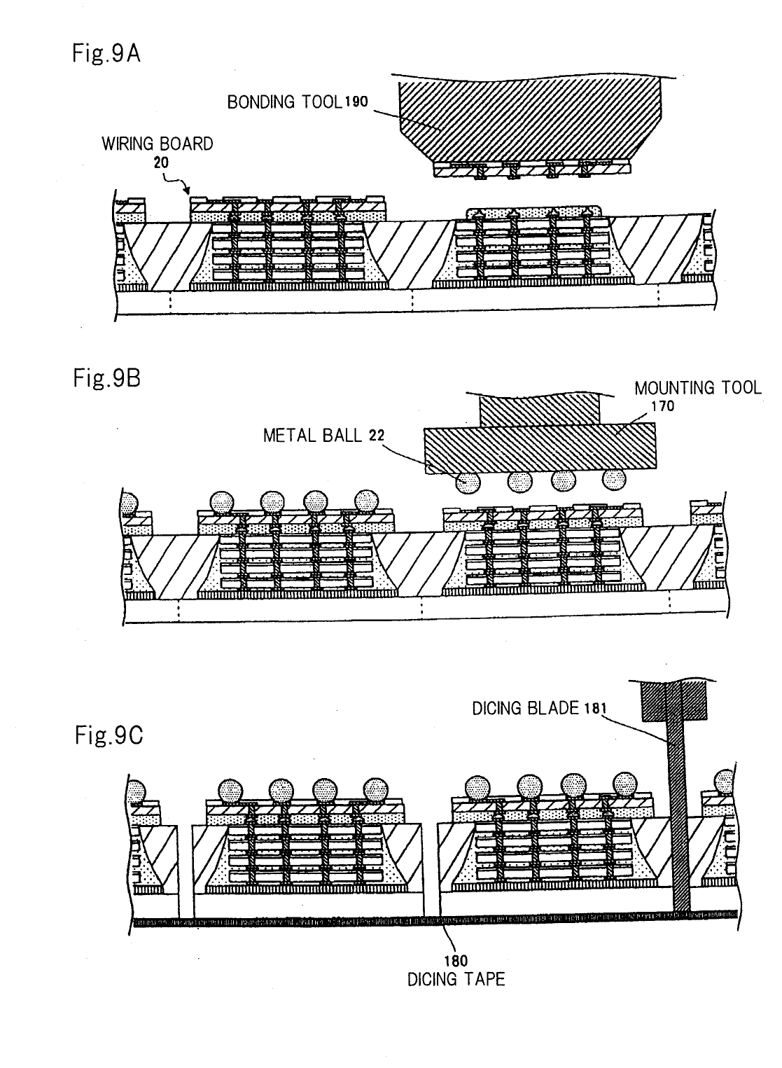

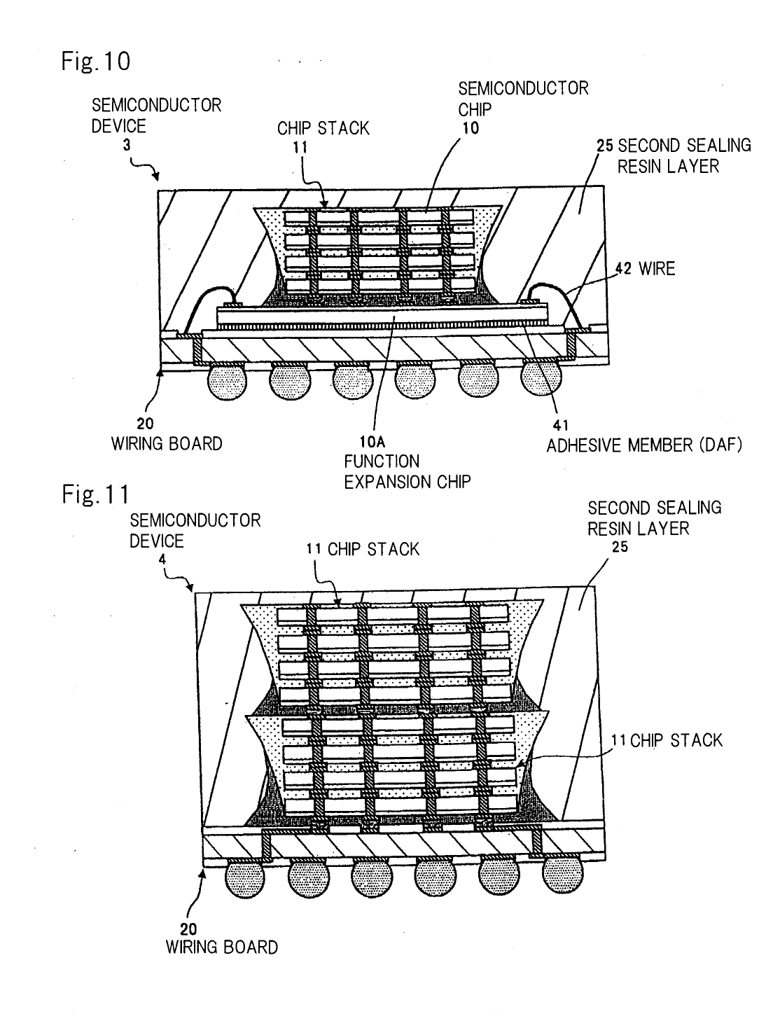

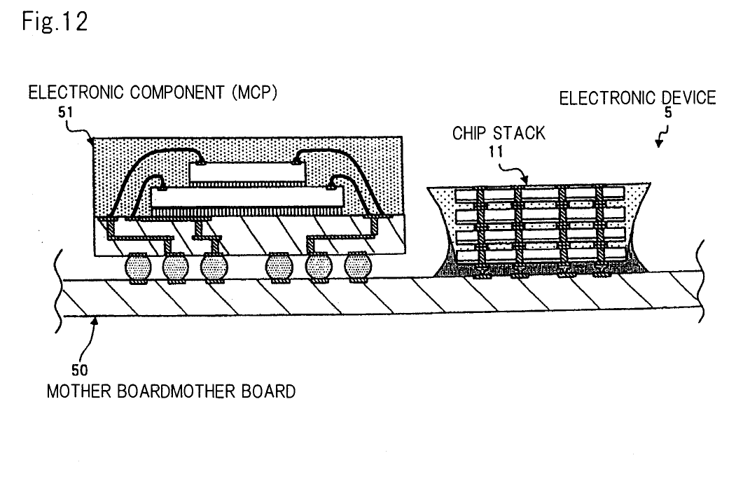

FIG. 2B is a cross-sectional view showing an exemplary configuration of the adsorption stage for use in the manufacturing of the chip stack shown in FIG. 1;

FIGS. 3A-3C are cross-sectional views showing an exemplary procedure for assembling the chip stack shown in FIG. 1;

FIGS. 4A-4D are cross-sectional views showing an exemplary procedure for assembling the chip stack shown in FIG. 1;

FIGS. 5A-5C are cross-sectional views showing an exemplary procedure for assembling the semiconductor device shown in FIG. 1;

FIGS. 6A-6C are cross-sectional views showing an exemplary procedure for assembling the semiconductor device shown in FIG. 1;

FIG. 7 is a cross-sectional view showing an exemplary configuration of a semiconductor device according to a second embodiment;

FIGS. 8A-8D are cross-sectional views showing an exemplary procedure for assembling the semiconductor device shown in FIG. 7;

FIGS. 9A-9C are cross-sectional views showing an exemplary procedure for assembling the semiconductor device shown in FIG. 7;

FIG. 10 is a cross-sectional view showing an exemplary configuration of a semiconductor device according to a third embodiment;

FIG. 11 is a cross-sectional view showing an exemplary configuration of a semiconductor device according to a fourth embodiment; and

FIG. 12 is a cross-sectional view showing an exemplary configuration of an electronic device which comprises the chip stack shown in FIG. 1.

### DETAILED DESCRIPTION OF THE PREFERRED EMBODIMENTS

Next, the present invention will be described with reference to the drawings.

### First Embodiment

FIG. 1 is a cross-sectional view showing an exemplary configuration of a semiconductor device according to a first embodiment.

As shown in FIG. 1, semiconductor device 1 according to the first embodiment comprises chip stack 11 which includes a plurality of stacked semiconductor chips 10, each having through electrodes, and wiring board 20 to which chip stack 11 is securely connected. Chip stack 11 comprises, for example, a stack of four semiconductor chips 10, each formed with a memory circuit.

Semiconductor chip 10 comprises a plurality of bump electrodes 12 on the one surface on which circuits are formed and the other surface on which no circuits are formed, where bump electrodes 12 on the one surface are connected to bump electrodes 12 on the other surface, respectively, through wires 13. Respective semiconductor chips 10 are connected to each other by through electrodes 13 by way of bump electrodes 12.

Chip stack 11 comprises first sealing resin layer 14 which fills gaps between respective semiconductor chips 10 and has a substantially trapezoidal cross-section, when seen from a side view. First sealing resin layer 14 is formed, for example, using a known underfill material.

Wiring board 20 formed with a predetermined wiring pattern is securely connected onto semiconductor chip 10 which is disposed proximate to a shorter side (top) of substantially trapezoidal first sealing resin layer 14. Wiring board 20 used herein is, for example, a glass epoxy board which is formed with predetermined wiring patterns on both surfaces, where each wire is covered with an insulating film such as a solder resist film, except for connection pads and lands, later described.

On one surface of wiring board 20, a plurality of connection pads 21 are formed for connection with chip stack 11, while on the other surface of the same, a plurality of lands 23 are formed for connecting metal balls 22 which serve as external terminals. These connection pads 21 are connected to predetermined lands 23 through wires. Lands 23 are arranged at predetermined intervals on the other surface of wiring board 20, for example, in a lattice shape.

Wire bump 15 made, for example, of Au, Cu or the like is formed on each bump electrode 12 on the surface of semiconductor chip 10 disposed proximate to the shorter side (top) of substantially trapezoidal first sealing resin layer 14, and wire bump 15 is connected to connection pad 21 on wiring board 20. Also, chip stack 11 is securely adhered to wiring board 20 with adhesive member 24 such as NCP (Non Conductive Paste) or the like, such that adhesive member 24 protects a bonding site of wire bump 15 with connection pad 21 of wiring board 20.

Chip stack 11 on wiring board 20 is sealed by second sealing resin layer 25, and metal balls 22, which serve as external terminals of semiconductor device 1, are connected to a plurality of lands 23, respectively, on the other surface of wiring board 20 on which chip stack 11 is not mounted.

Next, a method of manufacturing the semiconductor device according to the first embodiment, shown in FIG. 1, will be described with reference to the drawings.

FIG. 2A is a perspective view showing an exemplary configuration of an adsorption stage for use in the manufacturing of the chip stack shown in FIG. 1, and FIG. 2B is a cross-sectional view showing an exemplary configuration of the adsorption stage for use in the manufacturing of the chip stack shown in FIG. 1. FIGS. 3A-3C and FIGS. 4A-4D are cross-sectional views showing exemplary procedures for assembling the chip stack shown in FIG. 1.

For manufacturing semiconductor device 1 according to the first embodiment, a plurality of semiconductor chips 10, each having through electrodes 13, are first provided. Semiconductor chip 10 comprises a substantially rectangular plate-shaped semiconductor substrate made of Si or the like, and a predetermined circuit such as a memory circuit or the like formed on one surface of the semiconductor substrate.

Semiconductor chip 10 is placed on adsorption stage 100 shown in FIG. 2A, with the one surface thereof formed with a predetermined circuit directed upward. As shown in FIG. 2A, adsorption stage 100 comprises recess 101 such that semiconductor chip 10 is fitted into recess 101.

Semiconductor chip 10 is vacuum aspirated by a vacuum pump, not shown, through adsorption holes 102 pierced through adsorption stage 100 shown in FIGS. 2A and 2B, and is thereby held on adsorption stage 100 (see FIG. 3A).

Since recess 101 comprises tapered side surface 103, semiconductor chip 10 can be corrected in position when it is placed on adsorption stage 100. Also, side surfaces of semiconductor chip 10 placed on adsorption stage 100 come into contact with tapered side surfaces 103, so that semiconductor chip 10 can be appropriately adsorbed and held on adsorption stage 100.

Second-stair semiconductor chip 10 is mounted on first-stair semiconductor chip 10 held on adsorption stage 100, and bump electrodes 12 on the one surface of first-stair semiconductor chip 10 are bonded with bump electrodes 12 on the other surface of second stair semiconductor chip 10 on which no circuits are formed, thereby securely connecting second-stair semiconductor chip 10 on first-stair semiconductor chip 10.

For bonding bump electrodes 12 with each other, a thermo-compression bonding method may be used, where a predetermined load is applied to semiconductor chips 10, for example, by bonding tool 110 which is set at a high temperature (for example, approximately 300° C.), as shown in FIG. 3B. Alternatively, not limited to the thermo-compression bonding method, semiconductor chips 10 may be bonded with each other by using an ultrasonic compression bonding method which involves compression bonding semiconductor chips 10 while applying an ultrasonic wave to the same, or by using an ultrasonic thermo-compression bonding method which includes these two methods.

Third-stair semiconductor chip 10 is securely connected onto second-stair semiconductor chip 10 in a similar procedure to the above, and fourth-stair semiconductor chip 10 is securely connected onto third-stair semiconductor chip 10 in a similar procedure to the above (FIG. 3C).

A plurality of semiconductor chips 10 stacked in the foregoing procedure is placed on application sheet 121 adhered on stage 120, for example, as shown in FIG. 4A. A material employed for application sheet 121 exhibits poor wettability to first sealing resin layer 14 (underfill material) such as a fluorine-based sheet, a sheet coated with a silicone-based adhesive, or the like. Notably, application sheet 121 need not be directly adhered on stage 120, but may be adhered on any flat surface, for example, on a predetermined jig placed on stage 120.

A plurality of semiconductor chips 10 placed on application sheet 121 are supplied with underfill material 131 by dispenser 130 from the vicinity of their ends, as shown in FIG. 4B. Supplied underfill material 131 goes into gaps between semiconductor chips 10 by the action of capillary, while forming fillets around a plurality of stacked semiconductor chips 10, to fill the gaps between semiconductor chips 10.

In this embodiment, since a sheet made of a material which exhibits poor wettability to underfill material 131 is used for application sheet 121, underfill material 131 is restrained from spreading so that the width of the fillets will not increase.

After underfill material 131 is supplied, semiconductor chip 10, placed on application sheet 121, is cured (thermally treated) at a predetermined temperature, for example, approximately 150° C. to thermally set underfill material 131. As a result, first sealing resin layer 14 made of underfill material 131 is formed to surround the periphery of chip stack 11 and fill the gaps between semiconductor chips 10, as shown in FIG. 4C.

In this embodiment, since a sheet made of a material which exhibits poor wettability to underfill material 131 is used for application sheet 121, underfill material 131 is prevented from sticking to application sheet 121 while it is thermally set.

After thermally setting first sealing resin layer 14, chip stack 11 including this first sealing resin layer 14 is lifted up from application sheet 121, and stored, for example, in storage jig 140 shown in FIG. 4D. In this embodiment, since a sheet made of a material which exhibits poor wettability to underfill material 131 is used for application sheet 121, chip stack 11 can be readily lifted up from application sheet 121.

In this regard, if chip stack 11 shifts in position while underfill material 131 is being supplied to chip stack 11, chip stack 11 may be preliminarily secured onto application sheet 121 using a resin adhesive, and then underfill material 131 may be supplied to chip stack 11.

Wire bumps 15 are formed on bump electrodes 12 of topmost semiconductor chip 10 (disposed proximate to the shorter side (top) of substantially trapezoidal first sealing resin layer 14) of chip stack 11 stored in storage jig 140.

Wire bump 15 may be formed comprising: bonding a wire of Au, Cu or the like, which has been melted to form a ball-shaped at end, on each bump electrode 12 of semiconductor chip 10, by using a wire bonding machine, not shown, in accordance with an ultrasonic thermo-compression bonding method, by way of example, and then tearing off the wire.

While this embodiment shows an example of forming wire bumps 15 on bump electrodes 12 for facilitating the connection of chip stack 11 with wiring board 20, connection pads 21 of wiring board 20 may be directly connected to bump electrodes 12 of chip stack 11.

Next, a procedure for assembling the semiconductor device according to the first embodiment will be described with reference to FIGS. 5A-5C and FIGS. 6A-6C.

FIGS. 5A-5C and FIGS. 6A-6C are cross-sectional views showing an exemplary procedure for assembling the semiconductor device shown in FIG. 1. More specifically, FIGS. 5A-5C and FIGS. 6A-6C show an exemplary assembling procedure for forming a plurality of semiconductor devices 1 in batch.

Upon assembly of semiconductor device 1, wiring board 20 is prepared. Wiring board 20 comprises a plurality of product formation areas 26 arranged in a matrix shape. Each of product formation areas 26 later serves as wiring board 20 of semiconductor device 1. Each product formation area 26 is formed with wires in a predetermined pattern, and each wire is covered with an insulating film such as a solder resist film except for connection pads 21 and lands 23. Dicing lines are drawn between respective product formation areas 26 of wiring board 20 for singulating wiring board 20 into individual semiconductor devices 1.

A plurality of connection pads 21 are formed on one surface of wiring board 20 for connection with chip stack 11, while a plurality of lands 23 are formed on the other surface of wiring board 20 for connecting metal balls 22 which serve as external terminals. These connection pads 21 are connected to predetermined lands 23 through wires.

Once wiring board 20 has been prepared, insulating adhesive member 24, like NCP (non Conductive Paste), is coated onto each product formation area 26 of wiring board 20 by dispenser 150, as shown in FIG. 5A.

Next, the surface of chip stack 11, on which wire bumps 15 are not formed, is adsorbed and held by bonding tool 160 or the like, and mounted on each product formation area 26 of wiring board 20 (FIG. 5B). Then, each wire bump 15 of chip stack 11 is bonded with each connection pad 21 of wiring board 20, for example, using a thermo-compression bonding method. In this event, adhesive member 24 previously coated on wiring board 20 is filled between chip stack 11 and wiring board 20, so that chip stack 11 is securely adhered to wiring board 20 (FIG. 5C). Here, since first sealing resin layer 14 has been formed around chip stack 11 in a tapered shape, adhesive member 24 can be prevented from crawling up. In this way, it is possible to reduce damages, defective connections and the like of chip stack 11 due to adhesive member 24 sticking to bonding tool 160.

Wiring board 20 mounted with chip stacks 11 is set in a mold comprised of an upper piece and a lower piece included in a transfer mold machine, not shown, and is transferred to a process where a molding operation will occur.

The upper piece of the mold is formed with a cavity, not shown, which collectively covers a plurality of chip stacks 11, and chip stacks 11 mounted on wiring board 20 are received in the cavity.

Next, a sealing resin which has been heated to melt, is injected into the cavity defined in the upper piece of the mold to fill the cavity with the sealing resin such that the sealing resin covers entire chip stacks 11. The sealing resin used herein is, for example, a thermosetting resin such as an epoxy resin.

Subsequently, while the cavity is filled with the sealing resin, the sealing resin is thermally set at a predetermined temperature, for example, approximately 180° C., to form second sealing resin layer 25 which collectively covers respective chip stacks mounted on a plurality of product formation areas 26, as shown in FIG. 6A. Further, the sealing resin (second sealing resin layer 25) is baked at a predetermined temperature to completely set the same.

In this embodiment, since second sealing resin layer 25 is formed to cover entire chip stacks 11 after sealing semiconductor chips 10 of chip stacks 11 with first sealing resin (underfill material) 14, voids can be restrained from occurring in gaps between respective semiconductor chips 10.

The formation of second sealing resin layer 25 is followed by a transfer to a process to mount metal balls, where conductive metal balls 22 which serve as external terminals of the semiconductor device, for example, solder balls are connected to lands 23 formed on the other surface of wiring board 20, as shown in FIG. 6B.

In the process to mount metal balls, a plurality of metal balls 22 are adsorbed and held by mount tool 170 which comprises a plurality of adsorption holes which matches the positions of respective lands 23 on wiring board 20. Then, after flux is transferred to respective metal balls 22, respective metal balls 22 thus held are collectively mounted on lands 23 on wiring board 20.

After metal balls 22 have been mounted to all product formation areas 26, wiring board 20 is reflowed to connect each metal ball 22 to each land 23.

The completion of the connection of metal balls 22 is followed by a transfer to a board dicing process, where wiring board 20 is cut along predetermined dicing lines to separate respective product formation areas 26, thereby singulating semiconductor devices 1.

In the board dicing process, dicing tape 180 is adhered to second sealing resin layer 25 to support product formation areas 26. Then, as shown in FIG. 6C, wiring boards 20 is cut along predetermined dicing lines by dicing blade 181 included in a dicing machine, not shown, to separate respective product formation areas 26. After dicing for separation, dicing tape 180 is picked up from product formation areas 26 to complete CoC type semiconductor devices 1, as shown in FIG. 1.

According to this embodiment, chip stack 11 is previously created to include a plurality of stacked semiconductor chips 10, and then, chip stack 11 is securely connected to wiring board 20, so that thermal stress applied to connections between semiconductor chips and to semiconductor chips 1 is reduced in heat treatments performed during manufacturing, which are attributable to the difference in the thermal expansion coefficient and rigidity between semiconductor chips 10 and wiring board 20. Consequently, the rupture of connections between semiconductor chips 10 and the occurrence of cracks in semiconductor chips 10 can be prevented.

Also, since underfill material 131 which later serves as first sealing resin layer 14 is supplied to a plurality of stacked semiconductor chips 10 on application sheet 121 which is made of a material that exhibits poor wettability to the underfill material, the fillets formed of underfill material 131 can be stable in shape, and be reduced in width. Thus, an increase in the size of the package is prevented. Further, after supplying underfill material 131, chip stacks 11 can be readily lifted up from application sheet 121.

### Second Embodiment

FIG. 7 is a cross-sectional view showing an exemplary configuration of a semiconductor device according to a second embodiment.

As shown in FIG. 7, semiconductor device 2 according to the second embodiment comprises, in addition to chip stack 11 and wiring board 20 shown in the first embodiment, metal board (supporting board) 30 for supporting chip stack 11, where chip stack 11 is securely adhered to metal board 30 with adhesive member 31, like DAF (Die Attached Film). An iron/nickel alloy (42 alloy or the like), for example, is employed for metal board 30.

Wiring board 20 is securely connected to a surface of chip stack 11, which opposes a fixing surface of metal board 30, through wire bumps 15, in a similar manner to the first embodiment.

Warpage in semiconductor device 2 according to the second embodiment can be reduced by securing chip stack 11 on metal board 30. Also, since chip stack 11 is supported by metal board 30, it is possible to employ wiring board 20 which is smaller than metal board 30, so that the size of wiring board 20 can be optimally designed to conform to the number of external terminals.

Next, a procedure for assembling the semiconductor device according to the second embodiment will be described with reference to the drawings.

FIGS. 8A-8D and FIGS. 9A-9C are cross-sectional views showing an exemplary procedure for assembling the semiconductor device shown in FIG. 7. More specifically, FIGS. 8A-8D and FIGS. 9A-9C show an exemplary assembling procedure for forming a plurality of semiconductor devices 2 in batch.

Likewise, in the second embodiment, chip stack 11 is formed in a manner similar to the first embodiment to create chip stack 11 shown in FIG. 4C. Additionally, metal board 30 comprising a plurality of product formation areas 32 arranged in a matrix form is prepared as a supporting board for chip stack 11.

Upon completion of the preparation of metal board 30, insulating adhesive member 31, like DAF, is mounted on each product formation area 32 of metal board 30, as shown in FIG. 8A. Next, chip stacks 11 are securely adhered to respective product formation areas 32 of metal board 30 with insulating adhesive member 31, as shown in FIG. 8B.

Metal board 30 mounted with chip stack 11 is set in a mold comprised of an upper piece and a lower piece of a transfer mold machine, not shown, and is transferred to a process where a molding operation will occur.

The upper piece of the mold is formed with a cavity, not shown, which collectively covers a plurality of chip stacks 11, and chip stacks 11 mounted on metal board 30 are received in the cavity. In this event, an elastic sheet is disposed within the cavity, and the upper piece and lower piece are closed to cover the surface of topmost semiconductor chip 10 of chip stack 11 with the sheet. By doing so, a sealing resin, later described, is prevented from coming into contact with the surface of the topmost semiconductor chip of chip stack 11.

Next, a sealing resin which has been heated to melt, is injected into the cavity defined in the upper piece of the mold to fill the cavity with the sealing resin such that the sealing resin covers entire chip stacks 11. The sealing resin used herein is, for example, a thermosetting resin such as an epoxy resin.

Subsequently, while the cavity is filled with the sealing resin, the sealing resin is thermally cured at a predetermined temperature, for example, approximately 180° C., to form second sealing resin layer 25 which collectively covers respective chip stacks 11 mounted on a plurality of product formation areas 32, as shown in FIG. 8C. Further, the sealing resin (second sealing resin layer 25) is baked at a predetermined temperature to completely cure the same. In this event, since the surface of topmost semiconductor chip 10 of chip stack 11 is covered with the sheet, bump electrodes 12 expose without forming second sealing resin layer 25.

In this embodiment, since second sealing resin layer 25 is formed to cover entire chip stacks 11 after sealing semiconductor chips 10 of chip stacks 11 with first sealing resin (underfill material) 14, voids can be prevented from occurring in gaps between respective semiconductor chips 10.

Next, wire bumps 15 are formed on bump electrodes' 12 on the top of chip stack 11.

Wire bump 15 may be formed by bonding a bonding wire of Au, Cu or the like which has been melted to have a ball-shaped leading end, on bump electrode 12 of semiconductor chip 10, using a wire bonding machine, not shown, in accordance with an ultrasonic thermo-compression bonding method, by way of example, and then cutting the wire.

Alternatively, in this embodiment, solder bumps may be formed on bump electrodes 12 of semiconductor chip 10 instead of wire bumps 15. Also, while this embodiment shows an example of forming wire bumps 15 on bump electrodes 12 for facilitating the connection of chip stack 11 with wiring board 20, connection pads 21 of wiring board 20 may be directly connected to bump electrodes 12 of chip stack 11.

Next, adhesive member 24, like NCP, is selectively coated on the exposed surface of topmost semiconductor chip 10 of chip stack 11, in a manner similar to the first embodiment, as shown in FIG. 8D, and wiring board 20 is mounted on adhesive member 24 (FIG. 9A).

Wiring board 20 employed herein may be a polyimide board which has an area smaller than product formation area 32 of metal board 30, and is made in a substantially rectangular shape, by way of example, and formed with a wiring pattern, or a flexible board formed with a wiring pattern.

Next, wiring board 20 is adsorbed and held by bonding tool 160 or the like, and mounted on chip stack 11. Then, each wire bump 15 of chip stack 11 is bonded with each connection pad 21 of wiring board 20, for example, using a thermo-compression bonding method. In this event, adhesive member 24 (NCP material) previously applied on chip stack 11 is filled between chip stack 11 and wiring board 20, so that wiring board 20 is securely adhered on chip stack 11.

Since wiring board 20 which can be mounted on chip stack 11 has a smaller area than product formation area 32 of metal board 30 as described above, this embodiment can prevent a problem in which wiring boards 20 come into contact with each other on adjoining chip stacks 11, and a problem in which adhesive members 24 (NCP materials) come into contact with each other on adjoining chip stacks 11, when wiring boards 20 are mounted. Thus, wiring board 20 can be appropriately mounted on each chip stack 11.

Finally, metal ball 22 are mounted on each land 23 on the other surface of wiring board 20 using mount tool 170, in a manner similar to the first embodiment, as shown in FIG. 9B. Then, metal board 30 is cut by dicing blade 181 included in a dicing machine, not shown, to separate respective product formation areas 32, as shown in FIG. 9C, thus completing semiconductor device 2 shown in FIG. 7.

According to the second embodiment, chip stack 11 is previously created to comprise a plurality of stacked semiconductor chips 10, and this chip stack 11 is subsequently fixed on metal board (supporting board) 30, and wiring board 20 is securely connected to chip stack 11, so that thermal stress applied to connections between semiconductor chips 10 and to semiconductor chips 10 can be reduced in heat treatments performed during manufacturing, the stress being attributable to the difference in the thermal expansion coefficient and rigidity between semiconductor chips 10 and wiring board 20, the difference in thermal expansion coefficient and rigidity between semiconductor chips 10 and metal board (supporting board) 30, or variations in thermal distribution of the entire semiconductor device, and the like. Consequently, the rupture of connections between semiconductor chips 10 and the occurrence of cracks in semiconductor chips 10 can be prevented. semiconductor device 2 can be prevented from between semiconductor chips 10, and cracks running into semiconductor chips 10.

Also, since semiconductor device 2 according to the second embodiment comprises metal board 30, warpage in semiconductor device 2 can be reduced. Also, the provision of metal board 30 increases the mechanical strength of semiconductor device 2, and improves heat the dissipation properties of semiconductor device 2.

Further, since semiconductor device 2 according to the second embodiment has chip stack 11 supported by metal board 30, it is possible to employ wiring board 20 which is smaller than metal board 30, so that the size of wiring board 20 can be optimally designed to conform to the layout and the number of external terminals.

### Third Embodiment

FIG. 10 is a cross-sectional view showing an exemplary configuration of a semiconductor device according to a third embodiment.

As shown in FIG. 10, semiconductor device 3 according to the third embodiment comprises chip stack 11 shown in the first embodiment, and function expansion chip 10A, which is a semiconductor chip for providing different functions from those of semiconductor chips 10 included in chip stack 11, on wiring board 20, where chip stack 11 is securely connected to wiring board 20 through function expansion chip 10A.

Chip stack 11 shown in FIG. 10 is created in a procedure similar to the first embodiment. Function expansion chip 10A comprises a circuit (for example, a logic circuit) for providing functions different from those of semiconductor chips 10, on one surface of a substantially rectangular Si board, and a plurality of electrode pads formed near the periphery and center of the circuit.

Function expansion chip 10A has the other surface, not formed with the circuit, securely adhered to wiring board 20 using insulating adhesive member 41, like DAF. The electrode pads arranged near the periphery of function expansion chip 10A are connected to connection pads of wiring board 20 through conductive wires 42, while the electrode pads arranged near the center are connected to wire bumps 15 formed on the top of chip stack 11 by a flip-chip connection technique. Function expansion chip 10A, chip stack 11, and conductive wires 42 on wiring board 20 are sealed by second sealing resin layer 25.

While FIG. 10 shows an exemplary configuration of semiconductor device 3 which comprises function expansion chip 10A and chip stack 11 mounted on wiring board 20, semiconductor device 3 according to the third embodiment may alternatively comprise chip stack 11 and function expansion chip 10A mounted on metal board 30, and wiring board 20 mounted on top of them, in a manner similar to the second embodiment.

According to the third embodiment, in addition to similar benefits to the first embodiment, the provision of function expansion chip 10A having functions different from those of chip stack 11 enables a semiconductor device to provide a larger memory capacity or more functions.

### Fourth Embodiment

FIG. 11 is a cross-sectional view showing an exemplary configuration of a semiconductor device according to a fourth embodiment.

Semiconductor device 4 according to the fourth embodiment comprises a plurality of chip stacks 11 shown in the first embodiment, and moreover at least one chip stack 11 stacked on chip stack 11 mounted on wiring board 20. Here, each of mounted chip stacks 11 may provide the same functions or different functions.

Chip stacks 11 shown in FIG. 11 are created in a procedure similar to the first embodiment. For connecting chip stacks 11 to each other wire bumps 15, for example, are formed on respective bump electrodes 12 on the top of chip stack 11, and adhesive member 24, like NCP, is selectively coated. Then, chip stack 11 is mounted on adhesive member 24, and wire bumps 15 of lower chip stack 11 may be bonded with bump electrodes 12 of upper chip stack 11 using a thermo-compression bonding method or the like. In this event, chip stacks 11 are securely adhered to each other with adhesive member 24 coated on lower chip stack 11.

While FIG. 11 shows an exemplary configuration of semiconductor device 4 which comprises two chip stacks 11 stacked on wiring board 20, semiconductor device 4 according to the fourth embodiment may instead comprise two chip stacks 11 stacked on metal board 30, and wiring board 20 mounted on these chip stacks 11, in a manner similar to the second embodiment.

Also, while FIG. 11 shows an exemplary configuration of semiconductor device 4 which comprises two chip stacks 11 stacked on wiring board 20, the number of chip stacks 11 stacked on wiring board 20 is not limited to two, but a larger number of chip stacks 11 may be stacked one on another on wiring board 20 as long as a problem does not arise in terms of strength.

Further, semiconductor chip 4 according to the fourth embodiment may have chip stacks 11 fixed on wiring board 20 through function expansion chip 10A, as is the case with the third embodiment.

According to the fourth embodiment, the resulting semiconductor device can provide a yet larger memory capacity or even more functions, in addition to benefits similar to those of the first embodiment.

### Fifth Embodiment

FIG. 12 is a cross-sectional view showing an exemplary configuration of an electronic device according to a fifth embodiment.

The fifth embodiment proposes electronic device 5 which comprises chip stack 11 shown in the first through fourth embodiments.

Since chip stack 11 shown in the first through fourth embodiments has gaps between respective semiconductor chips 10 sealed with sealing resin layer (underfill material) 14, chip stack 11 can be assembled into electronic device 5 as is. FIG. 12 shows an example which comprises chip stack 11 shown, for example, in the first embodiment, and electronic component 51 formed by a packaging technique different from chip stack 11, for example, MCP (Multi-Chip Package), where chip stack 11 and electronic component 51 are mounted on mother board 50 which is formed with a predetermined wiring pattern.

Chip stack 11 shown in FIG. 12 is created in a procedure similar to the first embodiment. Like the first embodiment, wire bumps 15 may be formed on respective bump electrodes 12 on the top of chip stack 11, and adhesive member 24, like NCP, may be selectively coated on mother board 50. Subsequently, chip stack 11 may be mounted on mother board 50 by bonding tool 160, and connection pads of mother board 50 may be bonded with wire bumps 15 of chip stack 11, respectively, using a thermo-compression bonding method or the like. In this event, mother board 50 and chip stack 11 are securely fixed with adhesive member 24 coated on mother board 50.

According to this embodiment, by incorporating chip stack 11 shown in the first through fourth embodiments into electronic device 5, resulting electronic device 5 can be small in size but provide a larger memory capacity or more functions.

While the invention made by the inventors has been described with reference to several embodiments thereof, it should be understood that the present invention is not limited to the embodiments described above, but can be modified in various manners without departing from the spirit and scope of the invention.

For example, while the first through fifth embodiments have been described in connection with chip stack 11, given as an example, which comprises stacked semiconductor chips 10, each having through electrodes 13 and formed with a memory circuit, semiconductor chips 10 of chip stack 11 may include any combination of semiconductor chips which provide any functions, such as semiconductor chips formed with a memory circuit or a logic circuit, as long as semiconductor chips 10 are connected to each other using through electrodes 13.

Also, while the first through fifth embodiments have been described in connection with chip stack 11, given as an example, which comprises four stacked semiconductor chips 10, any number of semiconductor chips 10 may be stacked as long as semiconductor chips 10 are connected to each other using through electrodes 13.

Further, while the first through fifth embodiments have been described in connection with a BGA type semiconductor device, given as an example, which employs metal balls 22 as external terminals, the present invention can also be applied to semiconductor devices of other packaging techniques, such as LGA (Land Grid Array) and the like.

While the invention has been particularly shown and described with reference to exemplary embodiments thereof, the invention is not limited to these embodiments. It will be understood by those ordinarily skilled in the art that various changes in form and details may be made therein without departing from the spirit and scope of the present invention as defined by the claims.

What is claimed is:

1. A method of manufacturing a semiconductor device, comprising:
stacking a plurality of semiconductor chips while connecting respective through electrodes of said semiconductor chips to each other;
forming a first sealing resin layer for covering a periphery of said plurality of stacked semiconductor chips, and filling gaps between said semiconductor chips; and
securely connecting a chip stack including said plurality of stacked semiconductor chips and said first sealing resin layer to a wiring board which is formed with predetermined wiring.

2. The method of manufacturing a semiconductor device according to claim 1, further comprising forming a second sealing resin layer for covering said entire chip stack on said wiring board after securely connecting said chip stack to said wiring board.

3. A method of manufacturing a semiconductor device, comprising:
stacking a plurality of semiconductor chips while connecting respective through electrodes of said semiconductor chips to each other;
forming a first sealing resin layer for covering a periphery of said plurality of stacked semiconductor chips, and filling gaps between said semiconductor chips;
fixing a chip stack including said plurality of stacked semiconductor chips and said first sealing resin layer onto a supporting board;
forming a second sealing resin layer for covering said entire chip stack on said supporting board except for a surface of said chip stack which opposes a fixing surface of said supporting board; and
securely connecting a wiring board formed with predetermined wiring to the surface of said chip stack opposing the fixing surface of said supporting board.

4. The method of manufacturing a semiconductor device according to claim 1, further comprising securely connecting said chip stack on said wiring board through a function expansion chip which provides functions different from those of said semiconductor chips.

5. The method of manufacturing a semiconductor device according to claim 3, further comprising securely connecting said chip stack on said wiring board through a function expansion chip which provides functions different from those of said semiconductor chips.

6. The method of manufacturing a semiconductor device according to claim 1, further comprising:
creating a plurality of said chip stacks; and
further stacking at least one chip stack on said chip stacks.

7. The method of manufacturing a semiconductor device according to claim 3, further comprising:
creating a plurality of said chip stacks; and
further stacking at least one chip stack on said chip stacks.

8. The method of manufacturing a semiconductor device according to claim 1, further comprising:
placing said plurality of stacked semiconductor chips on an application sheet;
supplying an underfill material to said plurality of stacked semiconductor chips; and
setting said underfill material while said plurality of stacked semiconductor chips are kept placed on said application sheet to form said first sealing resin layer.

9. The method of manufacturing a semiconductor device according to claim 3, further comprising:
placing said plurality of stacked semiconductor chips on an application sheet;
supplying an underfill material to said plurality of stacked semiconductor chips; and
setting said underfill material while said plurality of stacked semiconductor chips are kept placed on said application sheet to form said first sealing resin layer.

10. The method of manufacturing a semiconductor device according to claim 8, wherein said application sheet is made of a material which exhibits poor wettability to said underfill material.

11. The method of manufacturing a semiconductor device according to claim 9, wherein said application sheet is made of a material which exhibits poor wettability to said underfill material.

12. A method comprising:
stacking a plurality of semiconductor chips with gaps between adjacent ones of the semiconductor chips;
filling the gaps between the adjacent ones of the said semiconductor chips with a first resin to form a chip stack structure; and
mounting the chip stack structure on a wiring board.

13. The method according to claim 12, further comprising covering the chip stack structure with a second resin after mounting the chip stack structure on the wiring board.

14. The method according to claim 12, further comprising intervening a function expansion chip between the chip stack structure and the wiring board, the function expansion chip providing functions different from the semiconductor chips of chip stack structure.

15. The method according to claim 12, wherein the filling the gaps between the adjacent ones of the semiconductor chips with a first resin includes placing the stacked semiconductor chips on an application sheet; supplying the first resin to the stacked semiconductor chips on the application sheet to fill the gaps of the stacked semiconductor chips; curing the first resin of the gaps of the stacked semiconductor chips on the application sheet to form the chip stack structure; and removing the application sheet from the chip stack structure.

16. The method according to claim 15, wherein the application sheet is made of a material which exhibits poor wettability to the first resin.

17. The method according to claim 12, wherein the stacked semiconductor chips are electrically connecting by a through electrode of the semiconductor chips to each other.

18. The method according to claim 12, wherein the first resin is an underfill material.
